(19) United States
(12) Patent Application Publication
(10) Pub. No.: US 2011/0062527 A1
(43) Pub. Date: Mar. 17, 2011

(54) SEMICONDUCTOR APPARATUS AND METHOD FOR MANUFACTURING SAME

(75) Inventors: Tomoaki SHINO, Mie-ken (JP); Mitsuhiro Noguchi, Kanagawa-ken (JP)

(73) Assignee: Kabushiki Kaisha Toshiba, Tokyo (JP)

(21) Appl. No.: 12/876,596

(22) Filed: Sep. 7, 2010

(30) Foreign Application Priority Data
Sep. 17, 2009 (JP) 2009-215326

(51) Int. Cl. H01L 27/092; H01L 21/8238

(52) U.S. Cl. 257/369; 438/221; 257/E21.632; 257/E27.062

(57) ABSTRACT

In one embodiment, a semiconductor apparatus is disclosed. The apparatus includes: an element-isolation insulating film formed on a major surface of a semiconductor layer, the element-isolation insulating film having a first opening and a second opening; an n-type MOSFET provided in the first opening; and a p-type MOSFET provided in the first opening. An upper face of a portion of the element-isolation insulating film adjacent to a source/drain region of the n-type MOSFET is positioned below an upper face of the source/drain region of the n-type MOSFET. An upper face of a portion of the element-isolation insulating film adjacent to a source/drain region of the p-type MOSFET is positioned above an upper face of the source/drain region of the p-type MOSFET.

### CROSS-REFERENCE TO RELATED APPLICATIONS

This application is based upon and claims the benefit of priority from the prior Japanese Patent Application No. 2009-215326, filed on Sep. 17, 2009; the entire contents of which are incorporated herein by reference.

### FIELD

Embodiments described herein elates generally to a semiconductor apparatus and a method for manufacturing the same.

### BACKGROUND

As (arsenic), P (phosphorus), and the like are known as impurities for forming the source and drain region of an n-type MOSFET. The profile of As is steeper than that of P during ion implantation because the As atom has a relatively large atomic number. Also, because the diffusion coefficient of As in Si is smaller than that of P, the profile of As is steeper than that of P after heating processes. Therefore, it is favorable to use the ion implantation of As to manufacture low-cost scaled n-type MOSFETs.

However, crystal defects are undesirably induced when performing heating processes after the ion implantation of As in high doses. Unfortunately, such crystal defects increase PN junction leaks and markedly increase the power consumption of the circuit.

JP-A 2004-228557 (Kokai) discusses a method to reduce stress accompanying oxidization by providing a buried insulating film below a silicon substrate surface to suppress crystal defects. However, when applying such a method to a p-type MOSFET, the mobility decreases and characteristics deteriorate.

### BRIEF DESCRIPTION OF THE DRAWINGS

FIG. 1 is a schematic cross-sectional view illustrating the configuration of a semiconductor apparatus according to a first embodiment;

FIGS. 2A to 2C are schematic views illustrating the configuration of the semiconductor apparatus according to the first embodiment;

FIG. 3 is a graph illustrating characteristics of the semiconductor apparatus;

FIGS. 4A to 4C are schematic cross-sectional views in order of the processes, illustrating a method for manufacturing the semiconductor apparatus according to the first embodiment;

FIGS. 5A to 5C are schematic cross-sectional views in order of the processes, illustrating the method for manufacturing the semiconductor apparatus according to the first embodiment continuing from FIG. 4C;

FIGS. 6A to 6C are schematic cross-sectional views in order of the processes, illustrating the method for manufacturing the semiconductor apparatus according to the first embodiment continuing from FIG. 5C; and

FIG. 7 is a flowchart illustrating a method for manufacturing a semiconductor apparatus according to a second embodiment.

### DETAILED DESCRIPTION

In one embodiment, a semiconductor apparatus is disclosed. The apparatus includes an element-isolation insulating film, an n-type MOSFET and a p-type MOSFET. The element-isolation insulating film is formed on a major surface of a semiconductor layer. The element-isolation insulating film has a first opening and a second opening. The n-type MOSFET includes a first active region formed on the major surface of the semiconductor layer inside the first opening, the first active region including a first source region, a first drain region, and a first channel region provided between the first source region and the first drain region, a first gate insulating film provided on the first channel region, and a first gate electrode provided on the first gate insulating film. The p-type MOSFET includes a second active region formed on the major surface of the semiconductor layer inside the second opening, the second active region including a second source region, a second drain region, and a second channel region provided between the second source region and the second drain region, a second gate insulating film provided on the second channel region, and a second gate electrode provided on the second gate insulating film. A first upper face of a portion of the element-isolation insulating film is adjacent to the first source region and the first drain region. The first upper face is positioned below an upper face of the first source region and an upper face of the first drain region. A second upper face of a portion of the element-isolation insulating film is adjacent to the second source region and the second drain region. The second upper face is positioned above an upper face of the second source region and an upper face of the second drain region.

In one embodiment, a method for manufacturing a semiconductor apparatus is disclosed. The apparatus includes an element-isolation insulating film, an n-type MOSFET and a p-type MOSFET. The element-isolation insulating film is formed on a major surface of a semiconductor layer. The element-isolation insulating film has a first opening and a second opening. The n-type MOSFET includes a first active region, a first gate insulating film, and a first gate electrode, the first active region being provided on a first semiconductor layer inside the first opening and including a first source region, a first drain region, and a first channel region provided between the first source region and the first drain region, the first gate insulating film being provided on the first channel region, the first gate electrode being provided on the first gate insulating film. The p-type MOSFET includes a second active region, a second gate insulating film, and a second gate electrode, the second active region being provided on a second semiconductor layer inside the second opening and including a second source region, a second drain region, and a second channel region provided between the second source region and the second drain region, the second gate insulating film being provided on the second channel region, the second gate electrode being provided on the second gate insulating film. The method includes: making a recess in the major surface of the semiconductor layer and filling an insulating material into the recess to form the element-isolation insulating film having the first opening and the second opening, an upper face of the element-isolation insulating film being positioned above an upper face of the semiconductor layer and; forming the first gate insulating film on a first semiconductor region inside the first opening, forming the first gate electrode on the first gate insulating film, forming the second gate insulating film on a second semiconductor region inside the second opening, and forming the second gate electrode on the second gate insulating film; etching the element-isolation insulating film adjacent to a first exposed region of the first semiconductor region using a first mask as a mask to recess an upper face of the element-isolation insulating film adjacent to the first exposed region to be lower than an upper face of the first exposed region, the first exposed region being not covered with the first gate insulating film and the first gate electrode, the first mask covering the second semiconductor region, the second gate insulating film, the second gate electrode, and the element-isolation insulating film adjacent to the second semiconductor region; implanting an n-type impurity into the first exposed region using the first mask as a mask; implanting a p-type impurity into a second exposed region of the second semiconductor region using a second mask as a mask, the second exposed region being not covered with the second gate insulating film and the second gate electrode, the second mask covering the first semiconductor region, the first gate insulating film, the first gate electrode, and the element-isolation insulating film adjacent to the first semiconductor region; and performing heat treatment of the first exposed region and the second exposed region to form the first source region, the first drain region, the second source region, and the second drain region.

Exemplary embodiments of the invention will now be described with reference to the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

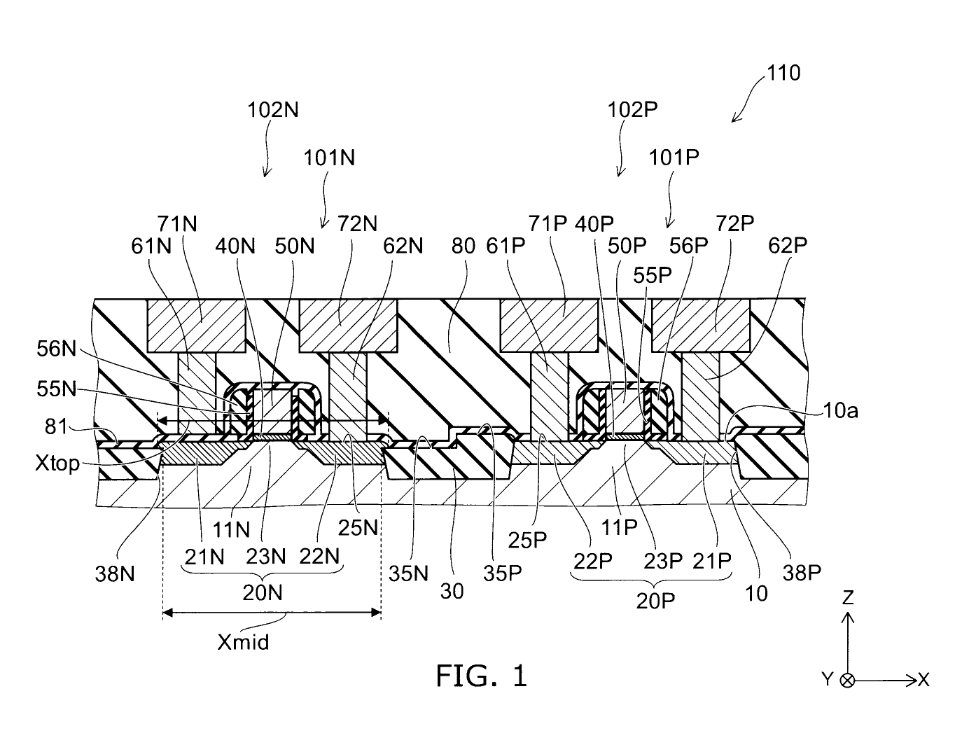

FIG. 1 is a schematic cross-sectional view illustrating the configuration of a semiconductor apparatus according to a first embodiment.

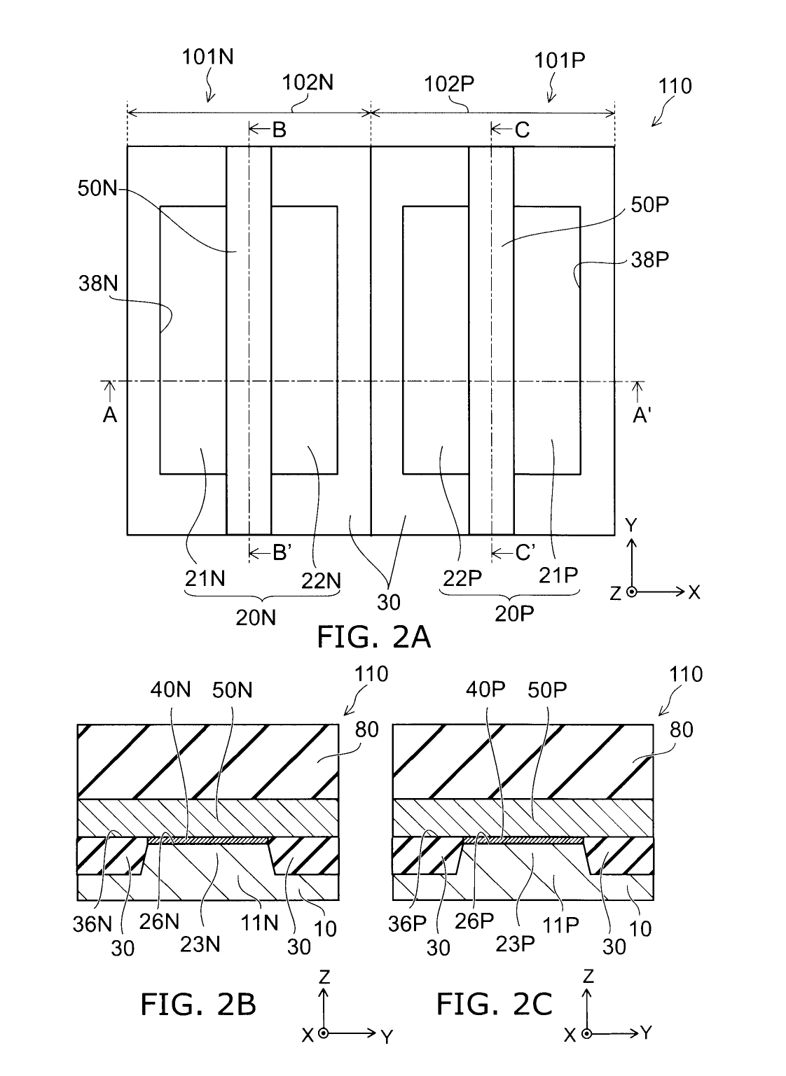

FIGS. 2A to 2C are schematic views illustrating the configuration of the semiconductor apparatus according to the first embodiment.

Namely, FIG. 1 is a cross-sectional view along line A-A′ of FIG. 2A. FIG. 2B is a cross-sectional view along line B-B′ of FIG. 2A. FIG. 2C is a cross-sectional view along line C-C′ of FIG. 2A.

As illustrated in FIG. 1 and FIGS. 2A to 2C, a semiconductor apparatus 110 according to this embodiment is a complementary MOSFET (Metal Oxide Semiconductor Field Effect Transistor).

The semiconductor apparatus 110 includes an element-isolation insulating film 30 formed on a semiconductor layer, an n-type MOSFET, and a p-type MOSFET. Each of the MOSFETs includes a gate electrode, a source, and a drain. The gate electrode is formed via a gate insulating film on an active region surrounded by the element-isolation insulating film 30. The source and the drain are formed with the gate electrode interposed therebetween.

In other words, the semiconductor apparatus 110 includes the element-isolation insulating film 30, an n-type MOSFET 101N, and a p-type MOSFET 101P.

The element-isolation insulating film 30 is formed on a major surface 10a of a semiconductor layer 10 and has a first opening 38N and a second opening 38P.

The n-type MOSFET 101N is provided in the interior of the first opening 38N. The n-type MOSFET 101N includes a first active region 20N, a first gate insulating film 40N, and a first gate electrode 50N.

The first active region 20N is formed on the major surface 10a of the semiconductor layer 10 inside the first opening 38N. In other words, the first active region 20N is provided in a p-well 11N (the first semiconductor region) inside the first opening 38N. The first active region 20N includes a first source region 21N, a first drain region 22N, and a first channel region 23N provided between the first source region 21N and the first drain region 22N. In other words, the first source region 21N and the first drain region 22N are provided apart from each other; and the first channel region 23N is provided therebetween.

The first gate insulating film 40N is provided on the first channel region 23N.

The first gate electrode 50N is provided on the first gate insulating film 40N.

The p-type MOSFET 101P is provided in the interior of the second opening 38P. The p-type MOSFET 101P includes a second active region 20P, a second gate insulating film 40P, and a second gate electrode 50P.

The second active region 20P is formed on the major surface 10a of the semiconductor layer 10 inside the second opening 38P. In other words, the second active region 20P is provided in an n-well 11P (the second semiconductor region) inside the second opening 38P. The second active region 20P includes a second source region 21P, a second drain region 22P, and a second channel region 23P provided between the second source region 21P and the second drain region 22P. In other words, the second source region 21P and the second drain region 22P are provided apart from each other; and the second channel region 23P is provided therebetween.

The second gate insulating film 40P is provided on the second channel region 23P.

The second gate electrode 50P is provided on the second gate insulating film 40P.

In the semiconductor apparatus 110, a first upper face 35N of the portion of the element-isolation insulating film 30 adjacent to the first source region 21N and the first drain region 22N is positioned below upper faces 25N of the first source region 21N and the first drain region 22N. A second upper face 35P of the portion of the element-isolation insulating film 30 adjacent to the second source region 21P and the second drain region 22P is positioned above upper faces 25P of the second source region 21P and the second drain region 22P.

“Above” refers to the direction from the interior of the semiconductor layer 10 progressing toward the major surface 10a side where the element-isolation insulating film 30 is provided. “Below” refers to the direction from the major surface 10a side progressing toward the interior of the semiconductor layer 10.

Herein, a direction perpendicular to the major surface 10a of the semiconductor layer 10 is taken as a Z axis direction. “Above” refers to the positive Z axis direction; and “below” refers to the negative Z axis direction.

A direction from the first source region 21N toward the first drain region 22N is taken as an X axis direction (the first direction). The X axis direction is perpendicular to the Z axis direction. A direction perpendicular to the Z axis direction and the X axis direction is taken as a Y axis direction. The first gate electrode 50N is extended to the Y axis direction.

In this specific example, the second source region 21P opposes the second drain region 22P in the X axis direction; and the direction in which the second source region 21P opposes the second drain region 22P is parallel to the direction in which the first source region 21N opposes the first drain region 22N. However, the embodiment is not limited thereto. The direction in which the second source region 21P opposes the second drain region 22P may be different from the direction in which the first source region 21N opposes the first drain region 22N.

The region in which the n-type MOSFET 101N is provided is taken as an n-side region 102N. The region in which the p-type MOSFET 101P is provided is taken as a p-side region 102P. The boundary between the n-side region 102N the p-side region 102P is positioned at any position in the width direction of the element-isolation insulating film 30 formed between the n-type MOSFET 101N and the p-type MOSFET 101P.

In the n-side region 102N, the first upper face 35N of the element-isolation insulating film 30 is positioned below the upper faces 25N of the first source region 21N and the first drain region 22N of the n-type MOSFET 101N. Therefore, the first source region 21N and the first drain region 22N are not pressed by the first upper face 35N of the element-isolation insulating film 30 in the case where, for example, the volume of the first source region 21N and the first drain region 22N tends to expand when the first source region 21N and the first drain region 22N are doped with a high concentration of As. Therefore, stress is not stored in the first source region 21N and the first drain region 22N. Thereby, crystal defects are suppressed.

On the other hand, in the p-side region 102P, the second upper face 35P of the element-isolation insulating film 30 is positioned above the upper faces 25P of the second source region 21P and the second drain region 22P of the p-type MOSFET 101P. In the p-type MOSFET 101P, BF₂ or B may be used to form the second source region 21P and the second drain region 22P. BF₂ and B have lower volume expansions than As. Therefore, crystal defects do not occur.

Generally, in the p-type MOSFET 101P, the mobility of a carrier in the channel region increases and the current driving ability increases by compressive stress acting in the X axis direction, i.e., compressive stress in the upper face 25P of the second drain region 22P. In such a case, in the p-side region 102P, the expansion of the second source region 21P and the second drain region 22P is restricted by the second upper face 35P of the element-isolation insulating film 30 by setting the second upper face 35P of the element-isolation insulating film 30 above the upper faces 25P of the second source region 21P and the second drain region 22P; and compressive stress is applied to the second channel region 23P. Thus, in the p-type MOSFET 101P, the mobility of carrier is increased by applying compressive stress. In other words, the high mobility characteristics of the p-type MOSFET can be maintained.

Thus, according to the semiconductor apparatus 110 according to this embodiment, the characteristics of the p-type MOSFET do not deteriorate; and a semiconductor apparatus can be provided in which crystal defects of the n-type MOSFET are suppressed.

In the case of, for example, a comparative example in which the upper face of the element-isolation insulating film is above the upper face of the source/drain region in both the n-type MOSFET and the p-type MOSFET, the source/drain region of the n-type MOSFET is restricted by the element-isolation insulating film. Therefore, in the case where the source/drain region of the n-type MOSFET tends to expand, an extremely large compressive stress is applied to the source/drain region of the n-type MOSFET; and crystal defects occur.

In the case of, for example, a comparative example in which the upper face of the element-isolation insulating film is below the upper face of the source/drain region in both the n-type MOSFET and the p-type MOSFET, crystal defects of the n-type MOSFET are suppressed; but the mobility of carrier of the p-type MOSFET undesirably decreases. In JP-A 2004-228557 (Kokai), a buried insulating film is provided below a silicon substrate surface; and stress accompanying oxidization is reduced. However, differences between the n-type MOSFET and the p-type MOSFET are not discussed; and by the technology discussed in JP-A 2004-228557 (Kokai), it is difficult to prevent the deterioration of the characteristics of the p-type MOSFET while also suppressing the crystal defects of the n-type MOSFET.

Conversely, in the semiconductor apparatus 110 according to this embodiment, the relationship between the upper face of the source/drain region and the upper face of the element-isolation insulating film 30 for the n-type MOSFET 101N and the p-type MOSFET 101P is changed; and the deterioration of the characteristics of the p-type MOSFET can be prevented while also suppressing the crystal defects of the n-type MOSFET.

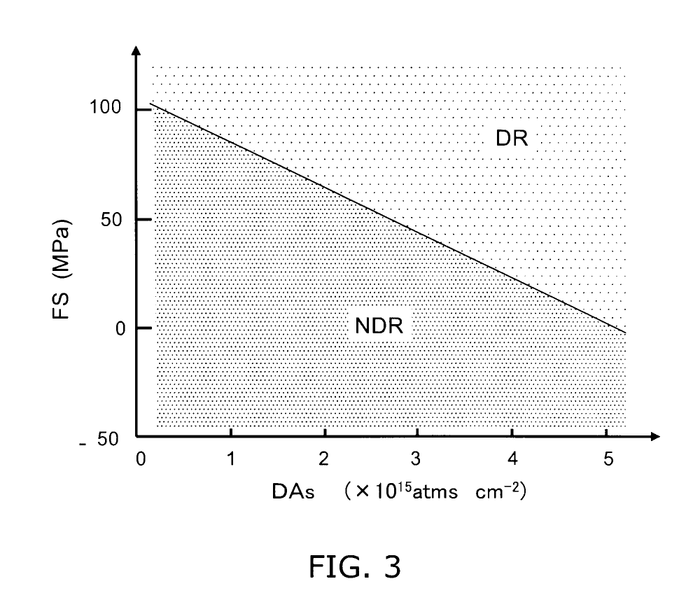

FIG. 3 is a graph illustrating characteristics of the semiconductor apparatus.

Namely, FIG. 3 illustrates the relationship between a dose amount DAs of As in the n-type MOSFET and the existence/absence of crystal defects for a comparative example in which the height of the upper face of the element-isolation insulating film 30 is above the upper face of the source/drain region. The dose amount DAs of As is plotted on the horizontal axis. A film stress FS of the element-isolation insulating film 30 during high temperatures is plotted on the vertical axis. The region on the lower side of the diagonal line in FIG. 3 is a crystal defect suppression region NDR having conditions in which crystal defects do not occur. The region on the upper side of the diagonal line is a crystal defect occurrence region DR having conditions in which crystal defects occur.

As illustrated in FIG. 3, generally, the existence/absence of crystal defects has a relationship also with the element-isolation insulating film 30. The film stress FS of the element-isolation insulating film 30 at high temperatures normally is about 50 to 70 MPa. Accordingly, in the case where the dose amount DAs of As is 3×10¹⁵ atoms/cm², crystal defects occur in the configuration of the comparative example.

During the ion implantation performed to form the source/drain region, an impurity is distributed in the outermost surface of the semiconductor layer 10. Here, it is necessary that the implantation is performed with a dose amount DAs of about 3×10¹⁵ atoms/cm² to sufficiently reduce the contact resistance and the parasitic resistance. In the comparative example, crystal defects occur at such a dose amount DAs.

Conversely, in the semiconductor apparatus 110 according to this embodiment, the first upper face 35N of the portion of the element-isolation insulating film 30 adjacent to the first source region 21N and the first drain region 22N is positioned below the upper faces 25N of the first source region 21N and the first drain region 22N. Therefore, stress does not increase in the first source region 21N and the first drain region 22N. Therefore, crystal defects do not occur even when using a dose amount DAs of As of 3×10¹⁵ atoms/cm². Thus, crystal defects, which easily occur particularly when As is used, can be suppressed in the semiconductor apparatus 110.

To suppress the crystal defects in the n-type MOSFET 101N, technology may be considered to reduce the film stress FS of the element-isolation insulating film 30. However, reducing the film stress FS of the element-isolation insulating film 30 also undesirably reduces the stress in the p-type MOSFET 101P; and the current driving ability of the p-type MOSFET 101P undesirably decreases.

Conversely, in the semiconductor apparatus 110 according to this embodiment, the crystal defects of the n-type MOSFET 101N can be suppressed while benefiting from the merits of increased current driving ability of the p-type MOSFET 101P due to the film stress FS of the element-isolation insulating film 30.

In the semiconductor apparatus 110, the first source region 21N and the first drain region 22N of the n-type MOSFET 101N overhang a portion of the upper face (the first upper face 35N) of the element-isolation insulating film 30 as illustrated in FIG. 1. In other words, volume expansion occurs in the first source region 21N and the first drain region 22N such that a portion of the upper face of the element-isolation insulating film 30 is covered with the first source region 21N and the first drain region 22N.

In other words, in the n-type MOSFET 101N, a width Xtop of the first active region 20N along the X axis direction (the first direction from the first source region 21N toward the first drain region 22N) at the upper faces 25N of the first source region 21N and the first drain region 22N is greater than a width Xmid of the first active region 20N along the X axis direction when the first active region 20N is cut in a plane including the first upper face 35N of the portion of the element-isolation insulating film 30 adjacent to the first source region 21N and the first drain region 22N. Thus, regarding the width of the active region (active area) along the direction (the X axis direction, i.e., the first direction) perpendicular to the alignment direction (the Y axis direction) of the first gate electrode 50N, the width (the width Xtop) at the height of the upper face of the source/drain region is greater than the width (the width Xmid) at the height of the upper face of the element-isolation insulating film 30.

By such a configuration, a portion of the upper face of the element-isolation insulating film 30 is covered with the first source region 21N and the first drain region 22N. Thereby, the volume of the first source region 21N and the first drain region 22N can expand; and the storage of stress in the first active region 20N can be mitigated.

In the p-type MOSFET 101P, the width of the second active region 20P along the X axis direction at the upper faces of the second source region 21P and the second drain region 22P is smaller than a width of the second active region 20P along the X axis direction below the upper faces. In other words, the second opening 38P of the element-isolation insulating film 30 opens downward; and the width of the second active region 20P along the X axis direction increases downward. By such a configuration, the second active region 20P is pressed by the element-isolation insulating film 30; stress along the X axis direction is effectively applied to the p-type MOSFET 101P; and the mobility of carrier increases.

As illustrated in FIG. 2B, an upper face 36N of the portion of the element-isolation insulating film 30 adjacent to the first channel region 23N is positioned above an upper face 26N of the first channel region 23N. In other words, the height of the upper face 36N of the element-isolation insulating film 30 is higher than the height of the upper face 26N of the first channel region 23N in a cross section of the n-type MOSFET 101N along the alignment direction (the Y axis direction) of the first gate electrode 50N of the n-type MOSFET 101N.

In the comparative example in which the height of the upper face 36N of the element-isolation insulating film 30 is lower than the upper face 26N of the first channel region 23N in the cross section of the first gate electrode 50N, a parasitic MOSFET having a low inversion threshold voltage is formed at the edge of the first channel region 23N; and the cut-off current of the n-type MOSFET 101N undesirably increases.

Conversely, in the semiconductor apparatus 110, the height of the upper face 36N of the portion of the element-isolation insulating film 30 adjacent to the first channel region 23N is set higher than the upper face 26N of the first channel region 23N. Therefore, the parasitic MOSFET is not formed; and the increase of the cut-off current of the n-type MOSFET 101N is suppressed.

In the p-type MOSFET 101P as well, similarly, an upper face 36P of the portion of the element-isolation insulating film 30 adjacent to the second channel region 23P is positioned above an upper face 26P of the second channel region 23P as illustrated in FIG. 2C. Thereby, the increase of the cut-off current of the p-type MOSFET 101P can be suppressed.

In this specific example, the first upper face 35N of the element-isolation insulating film 30 of the n-side region 102N has a Z axis direction position different from that of the second upper face 35P of the element-isolation insulating film 30 of the p-side region 102P; and the upper faces 25N of the first source region 21N and the first drain region 22N have a Z axis direction position substantially the same as that of the upper faces 25P of the second source region 21P and the second drain region 22P. Thereby, the Z axis direction position of the upper face of the first gate electrode 50N is substantially the same as the Z axis direction position of the upper face of the second gate electrode 50P.

However, the embodiment is not limited thereto. It is sufficient for the first upper face 35N of the element-isolation insulating film 30 to be positioned relatively below the upper faces 25N of the first source region 21N and the first drain region 22N in the n-side region 102N and for the second upper face 35P of the element-isolation insulating film 30 to be positioned relatively above the upper faces 25P of the second source region 21P and the second drain region 22P in the p-side region 102P.

However, by making the Z axis direction position of the upper face of the first gate electrode 50N substantially the same as the Z axis direction position of the upper face of the second gate electrode 50P as in the semiconductor apparatus 110, it is easy to planarize after forming an inter-layer insulating film described below. By maintaining the planarity, the focus margin of the subsequent lithography (e.g., to form the contact portions, etc.) is increased; and a semiconductor apparatus having a high yield can be manufactured.

The semiconductor layer 10 recited above may include a silicon substrate. The element-isolation insulating film 30, the first gate insulating film 40N, and the second gate insulating film 40P may include, for example, a silicon oxide film (silicon oxide). The first gate electrode 50N and the second gate electrode 50P may include, for example, polysilicon. However, the materials recited above are examples. Any material may be used in these components.

In the semiconductor apparatus 110, a first lower layer spacer 55N and a first upper layer spacer 56N are provided on the side face of the first gate insulating film 40N and the side face of the first gate electrode 50N. A second lower layer spacer 55P and a second upper layer spacer 56P are provided on the side face of the second gate insulating film 40P and the side face of the second gate electrode 50P. The first lower layer spacer 55N and the second lower layer spacer 55P may include, for example, a silicon oxide film based on TEOS (tetra ethyl ortho silicate). The first upper layer spacer 56N and the second upper layer spacer 56P may include, for example, a silicon nitride film.

A first source contact 61N, a first drain contact 62N, a second source contact 61P, and a second drain contact 62P are provided on the first source region 21N, the first drain region 22N, the second source region 21P, and the second drain region 22P, respectively. A first source interconnect 71N, a first drain interconnect 72N, a second source interconnect 71P, and a second drain interconnect 72P are connected to the first source contact 61N, the first drain contact 62N, the second source contact 61P, and the second drain contact 62P, respectively.

On the n-type MOSFET 101N and the p-type MOSFET 101P, a protective film 81 made of, for example, a silicon nitride film is provided. Thereupon, an inter-layer insulating film 80 made of, for example, a silicon oxide film, is provided. Contact holes and trenches are made in portions of the protective film 81 and the inter-layer insulating film 80 corresponding to the source/drain region; a conductive material is filled into the interiors thereof; and the various contacts and the various interconnects recited above are formed.

An example of a method for manufacturing the semiconductor apparatus 110 will now be described.

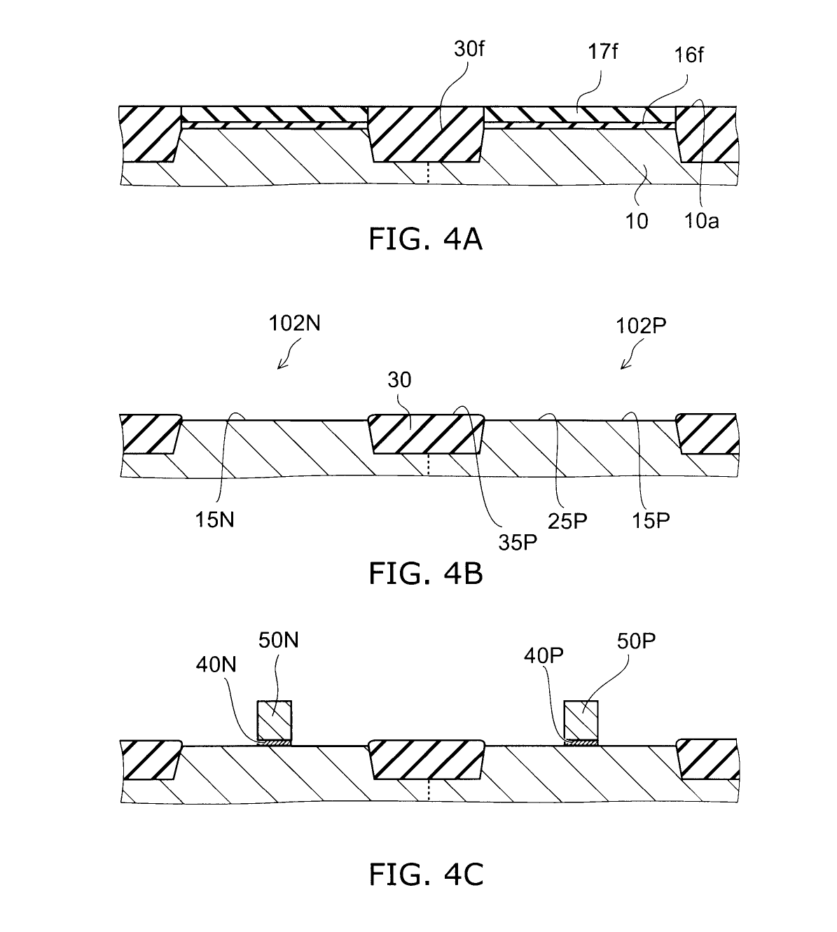

FIGS. 4A to 4C are schematic cross-sectional views in order of the processes, illustrating the method for manufacturing the semiconductor apparatus according to the first embodiment.

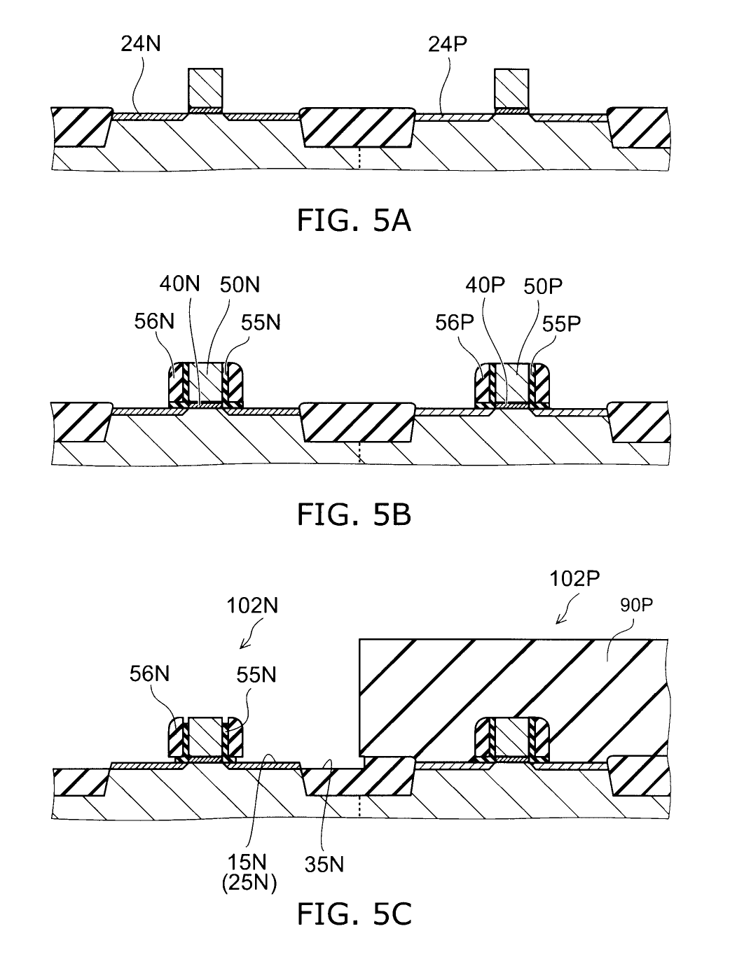

FIGS. 5A to 5C are schematic cross-sectional views in order of the processes, illustrating the method for manufacturing the semiconductor apparatus according to the first embodiment continuing from FIG. 4C.

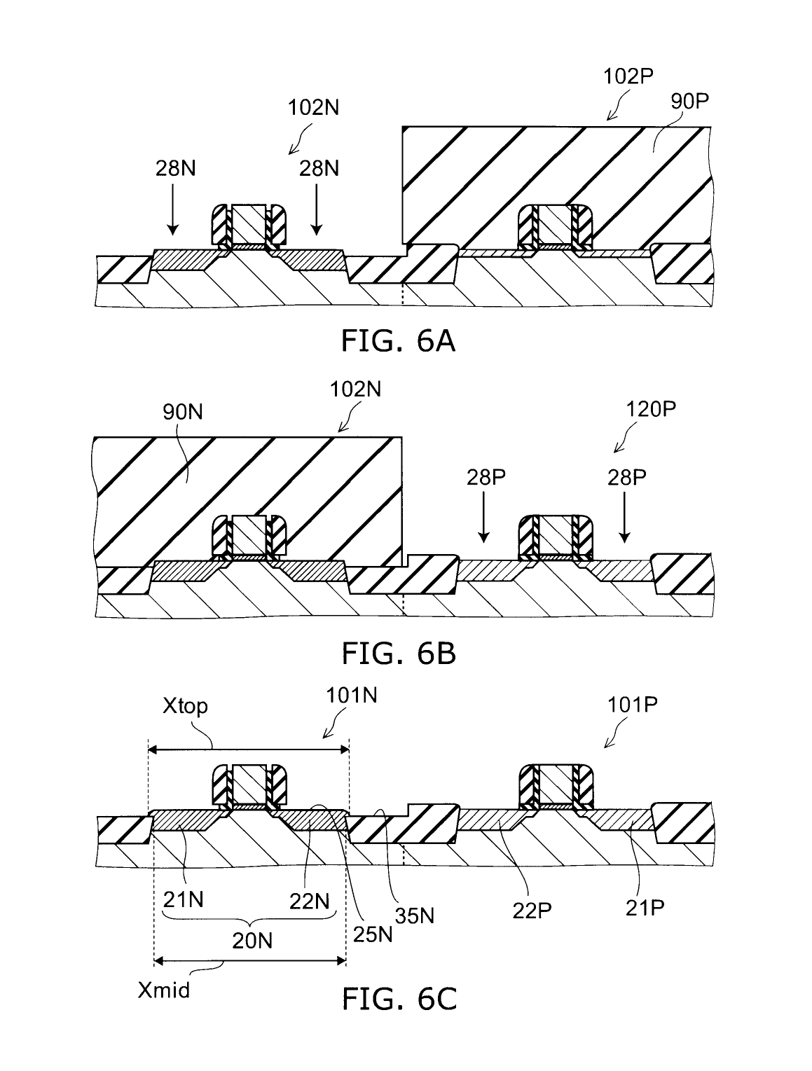

FIGS. 6A to 6C are schematic cross-sectional views in order of the processes, illustrating the method for manufacturing the semiconductor apparatus according to the first embodiment continuing from FIG. 5C.

As illustrated in FIG. 4A, a silicon oxide film 16f and a silicon nitride film 17f are deposited on the major surface 10a of the semiconductor layer 10 as an element separation mask. Then, the silicon oxide film 16f and the silicon nitride film 17f are removed in regions where the element-isolation insulating film 30 is to be formed; and trenches are made with a depth of, for example, about 300 nm (nanometers) in the semiconductor layer 10 by anisotropic etching. Thereupon, a silicon oxide film 30f is deposited and filled into the interiors of the trenches and subsequently planarized by CMP (Chemical Mechanical Polishing).

As illustrated in FIG. 4B, the silicon oxide film 16f and the silicon nitride film 17f of the element separation mask are removed to expose upper faces 15N and 15P on the major surface 10a side of the semiconductor layer 10. Thereby, the element-isolation insulating film 30 is formed. At this time, the upper face of the element-isolation insulating film 30 is positioned above the upper faces 15N and 15P of the semiconductor layer 10 in the Z axis direction.

In the case where the first upper face 35N of the element-isolation insulating film 30 is lower than the upper faces 15N and 15P of the semiconductor layer 10 in the n-side region 102N at this stage, a parasitic MOSFET is formed at the edge of the active region; and the nonuniformity of the heights of the upper faces of the gate electrodes causes a deterioration of the planarity of the inter-layer insulating film 80. Therefore, the upper face of the element-isolation insulating film 30 is positioned above the upper faces 15N and 15P of the semiconductor layer 10 in the Z axis direction for the n-side region 102N as well.

On the other hand, the configuration formed in this process, in which the upper face of the element-isolation insulating film 30 is positioned above the upper faces 15N and 15P of the semiconductor layer 10 in the Z axis direction, realizes a configuration in which the second upper face 35P of the portion of the element-isolation insulating film 30 adjacent to the p-type MOSFET 101P is positioned above the upper faces 25P of the second source region 21P and the second drain region 22P.

Then, as illustrated in FIG. 4C, a silicon oxide film forming the first gate insulating film 40N and the second gate insulating film 40P is formed, for example, by thermal oxidation of the upper face of the semiconductor layer 10. Then, a gate electrode material of polysilicon or amorphous silicon forming the first gate electrode 50N and the second gate electrode 50P is deposited. Using a resist pattern as a mask, the first gate insulating film 40N, the second gate insulating film 40P, the first gate electrode 50N, and the second gate electrode 50P are formed by anisotropic etching of the gate electrode material and the silicon oxide film.

Continuing as illustrated in FIG. 5A, an n-type impurity is ion implanted into the n-side region 102N using the first gate electrode 50N as a mask; and a p-type impurity is ion implanted into the p-side region 102P using the second gate electrode 50P as a mask. Then, by performing heat treatment, a source/drain extension region 24N of the n-side region 102N and a source/drain extension region 24P of the p-side region 102P are formed.

Then, as illustrated in FIG. 5B, spacers are formed on the side wall of the gate electrode by depositing a silicon oxide film based on TEOS and a silicon nitride film and performing anisotropic etching of these films. In other words, the first lower layer spacer 55N and the first upper layer spacer 56N are formed on the side face of the first gate insulating film 40N and the side face of the first gate electrode 50N. Then, the second lower layer spacer 55P and the second upper layer spacer 56P are formed on the side face of the second gate insulating film 40P and the side face of the second gate electrode 50P.

Continuing as illustrated in FIG. 5C, a first mask 90P is formed to cover the p-side region 102P. Using the first mask 90P as a mask, wet etching is performed with, for example, BHF (buffered hydrogen fluoride) and the like to etch the element-isolation insulating film 30 of the n-side region 102N. Thereby, the first upper face 35N of the element-isolation insulating film 30 is below the upper face 15N of the semiconductor layer 10, that is, below the upper faces 25N of the first source region 21N and the first drain region 22N of the n-type MOSFET 101N.

Then, as illustrated in FIG. 6A, using the first mask 90P as a mask, ion implantation is performed using As as an n-type impurity 28N with, for example, an acceleration energy of 30 keV (kilo-electron-volts) and a dose amount DAs of 3×10¹⁵ atoms/cm². Subsequently, the first mask 90P is removed.

At this time, the first mask 90P may be used as both a mask to prevent ion implantation into the p-side region 102P and as an etching mask of the element-isolation insulating film 30 of the n-side region 102N. As a result, processes can be simplified. The first lower layer spacer 55N exists on the side face of the first gate insulating film 40N during the etching of the element-isolation insulating film 30 of the n-side region 102N. As a result, the first lower layer spacer 55N functions as a protective film and prevents etching of the first gate insulating film 40N.

Subsequently, as illustrated in FIG. 6B, a second mask 90N is formed to cover the n-side region 102N. Using the second mask 90N as a mask, B is ion implanted as a p-type impurity 28P with, for example, an acceleration energy of 4 keV and a dose amount DAs of 3×10¹⁵ atoms/cm². Subsequently, the second mask 90N is removed.

Subsequently, as illustrated in FIG. 6C, heat treatment is performed to diffuse and activate the impurities to form the source/drain regions (the first source region 21N, the first drain region 22N, the second source region 21P, and the second drain region 22P). The conditions of the heat treatment may be, for example, RTA (Rapid Thermal Annealing) at a temperature of 1000° C. for 10 seconds.

At this time, due to volume expansion of the n-side region 102N into which As was implanted, the width Xtop of the first active region 20N at the height of the upper face 25N of the source/drain region is greater than the width Xmid of the first active region 20N at the height of the first upper face 35N of the element-isolation insulating film 30.

In such a process of conventional art, the active region including a high concentration of As is pressed by the element-isolation insulating film 30. Therefore, extremely high stress occurs in the active region; and crystal defects occur. According to the manufacturing method according to this embodiment, the active region including the high concentration of As is not pressed by the element-isolation insulating film 30. Therefore, it is possible for the volume to expand to mitigate the stress. Therefore, crystal defects do not occur.

Subsequently, a silicon nitride film is deposited as the protective film 81, i.e., a contact etching stopper; and a BPSG (Boron Phosphorous Silicate Glass) film is deposited as the inter-layer insulating film 80. The BPSG film is planarized by CMP. After making contact holes and interconnect trenches in the silicon nitride film and the BPSG film, the various contacts and the various interconnects are formed by filling, for example, a metal material into the contact holes and the interconnect trenches.

Thereby, the semiconductor apparatus 110 illustrated in FIG. 1 and FIGS. 2A to 2C can be constructed.

In the manufacturing method recited above, the process of etching the element-isolation insulating film 30 of the n-side region 102N using the first mask 90P covering the p-side region 102P as a mask is added to the conventional manufacturing method. Accordingly, the crystal defects of the n-type MOSFET 101N can be suppressed while maintaining the characteristics of the p-type MOSFET 101P without drastically increasing manufacturing costs.

The first mask 90P and the second mask 90N may include any insulating film and the like such as various resist materials.

Although the description recited above illustrates an example in which a stacked film of a silicon oxide film and a silicon nitride film is used as the spacer (the first lower layer spacer 55N, the first upper layer spacer 56N, the second lower layer spacer 55P, and the second upper layer spacer 56P) formed on the side wall of each of the gate electrodes, the embodiment is not limited thereto. For example, only the silicon oxide film or only the silicon nitride film may be used as the spacer.

Silicide may be formed on the gate electrodes to reduce the resistance. Silicide may be self-aligningly formed on the source/drain regions and on the gate electrodes.

### Second Embodiment

A second embodiment of the invention is a method for manufacturing a semiconductor apparatus having the configuration of the semiconductor apparatus 110 recited above.

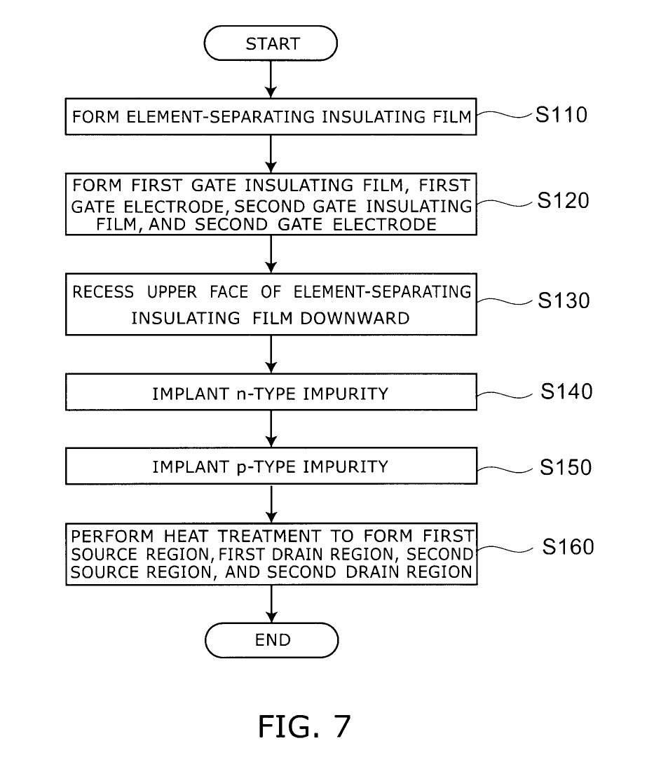

FIG. 7 is a flowchart illustrating the method for manufacturing the semiconductor apparatus according to the second embodiment.

In the method for manufacturing the semiconductor apparatus according to this embodiment, first, an element separation mask is formed on regions of the major surface 10a of the semiconductor layer 10 other than the regions where the element-isolation insulating film 30 is to be formed as illustrated in FIG. 7. Subsequently, a recess (e.g., a trench) is made in the major surface 10a of the semiconductor layer 10 using the element separation mask as a mask; an insulating material is filled into the recess; the element separation mask is removed; and the element-isolation insulating film 30 having the first opening 38N and the second opening 38P is formed so that the upper face is positioned above the upper faces 15N and 15P of the semiconductor layer 10 (step S110).

For example, the processing illustrated in FIGS. 4A and 4B is performed. The silicon oxide film 16f and the silicon nitride film 17f may be used as the element separation mask recited above.

The width of the recess (e.g., the trench) recited above along the X axis direction (a direction from the first opening 38N toward the second opening 38P) increases along a direction (above) from the interior of the semiconductor layer 10 toward the major surface 10a of the semiconductor layer 10. Thereby, compressive stress can be easily applied to the second channel region 23P; and the mobility of the p-type MOSFET 101P can be increased easily.

Then, the first gate insulating film 40N is formed on the first semiconductor region (the p-well 11N) inside the first opening 38N. The first gate electrode 50N is formed on the first gate insulating film 40N. The second gate insulating film 40P is formed on the second semiconductor region (the n-well 11P) inside the second opening 38P. The second gate electrode 50P is formed on the second gate insulating film 40P (step S120). For example, the processing illustrated in FIG. 4C is performed.

The first mask 90P covering the second semiconductor region, the second gate insulating film 40P, the second gate electrode 50P, and the element-isolation insulating film 30 adjacent to the second semiconductor region is used as a mask to etch the element-isolation insulating film 30 adjacent to the first exposed region of the first semiconductor region not covered with the first gate insulating film 40N and the first gate electrode 50N; and the first upper face 35N of the element-isolation insulating film 30 adjacent to the first exposed region is recessed below the upper face 25N of the first exposed region (step S130).

In other words, the first mask 90P covering the element-isolation insulating film 30 of the p-side region 102P, the second gate insulating film 40P, and the second gate electrode 50P is used as a mask to etch the element-isolation insulating film 30 of the n-side region 102N; and the first upper face 35N of the element-isolation insulating film 30 of the n-side region 102N is recessed below the upper face (e.g., the upper face 15N illustrated in FIG. 4B) of the semiconductor layer 10 of the n-side region 102N. For example, the processing illustrated in FIG. 5C is performed.

Then, the n-type impurity 28N is implanted into the first exposed region of the first semiconductor region recited above not covered with the first gate insulating film 40N and the first gate electrode 50N using the first mask 90P as a mask (step S140).

In other words, the n-type impurity 28N is implanted into the first semiconductor region of the n-side region 102N using the first mask 90P as a mask. The process, for example, illustrated in FIG. 6A is performed.

Then, a p-type impurity 28P is implanted into the second exposed region of the second semiconductor region not covered with the second gate insulating film 40P and the second gate electrode 50P using the second mask 90N covering the first semiconductor region, the first gate insulating film 40N, the first gate electrode 50N, and the element-isolation insulating film 30 adjacent to the first semiconductor region as a mask (step S150).

In other words, the p-type impurity 28P is implanted into the second semiconductor region of the p-side region 102P using the second mask 90N covering the n-side region 102N as a mask. The process, for example, illustrated in FIG. 6B is performed.

Then, heat treatment is performed on the first exposed region into which the n-type impurity was implanted and the second exposed region into which the p-type impurity was implanted to diffuse and activate the n-type impurity and the p-type impurity; and the first source region 21N, the first drain region 22N, the second source region 21P, and the second drain region 22P are formed (step S160). In other words, the process illustrated in FIG. 6C is performed.

Thereby, a semiconductor apparatus can be manufactured having suppressed crystal defects of the n-type MOSFET while maintaining the characteristics of the p-type MOSFET.

The sequence of the steps recited above is interchangeable within the extent of technical feasibility; and multiple steps may be implemented simultaneously within the extent of technical feasibility.

In the p-side region 102P, the height of the second upper face 35P of the element-isolation insulating film 30 adjacent to the source/drain region thereof is the same as that of conventional art. Therefore, good characteristics are maintained without deterioration of the characteristics of the p-type MOSFET 101P. In the n-side region 102N, the height of the first upper face 35N of the element-isolation insulating film 30 adjacent to the source/drain region thereof is lower than the height of the upper face 25N of the source/drain region. Therefore, the crystal defects due to the ion implantation of As are suppressed. As a result, a high performance complementary MOSFET can be manufactured without substantially increasing manufacturing costs.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may appropriately select specific configurations of components of semiconductor apparatuses such as semiconductor layers, element-isolation insulating films, semiconductor regions, source regions, drain regions, channel regions, active regions, gate insulating films, gate electrodes, inter-layer insulating films, protective films, contacts, interconnects, and the like from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all semiconductor apparatuses and methods for manufacturing semiconductor apparatuses practicable by an appropriate design modification by one skilled in the art based on the semiconductor apparatuses and the methods for manufacturing the semiconductor apparatuses described above as exemplary embodiments of the invention also are within the scope of the invention to the extent that the purport of the invention is included.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

1. A semiconductor apparatus, comprising:
an element-isolation insulating film formed on a major surface of a semiconductor layer, the element-isolation insulating film having a first opening and a second opening;
an n-type MOSFET including
a first active region formed on the major surface of the semiconductor layer inside the first opening, the first active region including a first source region, a first drain region, and a first channel region provided between the first source region and the first drain region,
a first gate insulating film provided on the first channel region, and
a first gate electrode provided on the first gate insulating film; and
a p-type MOSFET including
a second active region formed on the major surface of the semiconductor layer inside the second opening, the second active region including a second source region, a second drain region, and a second channel region provided between the second source region and the second drain region,
a second gate insulating film provided on the second channel region, and
a second gate electrode provided on the second gate insulating film,
a first upper face of a portion of the element-isolation insulating film adjacent to the first source region and the first drain region, the first upper face being positioned below an upper face of the first source region and an upper face of the first drain region,
a second upper face of a portion of the element-isolation insulating film adjacent to the second source region and the second drain region, the second upper face being positioned above an upper face of the second source region and an upper face of the second drain region.

2. The apparatus according to claim 1, wherein
a width of the first active region along a first direction from the first source region toward the first drain region at the upper face of the first source region and the upper face of the first drain region is greater than a width of the first active region along the first direction when the first active region is cut in a plane including the first upper face of the portion of the element-isolation insulating film adjacent to the first source region and the first drain region.

3. The apparatus according to claim 1, wherein an upper face of a portion of the element-isolation insulating film adjacent to the first channel region is positioned above an upper face of the first channel region.

4. The apparatus according to claim 3, wherein an upper face of a portion of the element-isolation insulating film adjacent to the second channel region is positioned above an upper face of the second channel region.

5. The apparatus according to claim 1, wherein an impurity included in the first source region and the first drain region includes As.

6. The apparatus according to claim 5, wherein a dose amount of As included in the first source region and the first drain region is not less than 3×10¹⁵ atoms/cm².

7. The apparatus according to claim 5, wherein an impurity included in the second source region and the second drain region includes B.

8. The apparatus according to claim 1, wherein compressive stress is applied to at least one of the second channel region and the upper face of the second drain region along a direction from the second source region toward the second drain region.

9. The apparatus according to claim 1, wherein at least one of the first source region and the first drain region overhang a portion of the first upper face of the element-isolation insulating film.

10. The apparatus according to claim 1, wherein a width of the second active region along a direction from the second source region toward the second drain region at the upper face of the second source region and the upper face of the second drain region is smaller than a width of the second active region along the direction from the second source region toward the second drain region when the second active region is cut in a plane below the upper face of the second source region and the upper face of the second drain region.

11. The apparatus according to claim 1, wherein a position of the upper face of the first source region and a position of the upper face of the first drain region along a direction perpendicular to the major surface of the semiconductor layer are substantially equal to a position of the upper face of the second source region and a position of the upper face of the second drain region along a direction perpendicular to the major surface of the semiconductor layer.

12. The apparatus according to claim 1, wherein a position of an upper face of the first gate electrode along a direction perpendicular to the major surface of the semiconductor layer is substantially equal to a position of an upper face of the second gate electrode along the direction perpendicular to the major surface of the semiconductor layer.

13. The apparatus according to claim 1, wherein the semiconductor layer is a silicon substrate.

14. The apparatus according to claim 1, wherein silicon oxide is included in at least one of the element-isolation insulating film, the first gate insulating film and the second gate insulating film.

15. The apparatus according to claim 1, wherein the first gate electrode and the second gate electrode include polysilicon.

16. A method for manufacturing a semiconductor apparatus, the apparatus including: an element-isolation insulating film formed on a major surface of a semiconductor layer, the element-isolation insulating film having a first opening and a second opening; an n-type MOSFET including a first active region, a first gate insulating film, and a first gate electrode, the first active region being provided on a first semiconductor layer inside the first opening and including a first source region, a first drain region, and a first channel region provided between the first source region and the first drain region, the first gate insulating film being provided on the first channel region, the first gate electrode being provided on the first gate insulating film; and a p-type MOSFET including a second active region, a second gate insulating film, and a second gate electrode, the second active region being provided on a second semiconductor layer inside the second opening and including a second source region, a second drain region, and a second channel region provided between the second source region and the second drain region, the second gate insulating film being provided on the second channel region, the second gate electrode being provided on the second gate insulating film, the method comprising:
making a recess in the major surface of the semiconductor layer and filling an insulating material into the recess to form the element-isolation insulating film having the first opening and the second opening, an upper face of the element-isolation insulating film being positioned above an upper face of the semiconductor layer and;
forming the first gate insulating film on a first semiconductor region inside the first opening, forming the first gate electrode on the first gate insulating film, forming the second gate insulating film on a second semiconductor region, inside the second opening and forming the second gate electrode on the second gate insulating film;
etching the element-isolation insulating film adjacent to a first exposed region of the first semiconductor region using a first mask as a mask to recess an upper face of the element-isolation insulating film adjacent to the first exposed region to be lower than an upper face of the first exposed region, the first exposed region being not covered with the first gate insulating film and the first gate electrode, the first mask covering the second semiconductor region, the second gate insulating film, the second gate electrode, and the element-isolation insulating film adjacent to the second semiconductor region;
implanting an n-type impurity into the first exposed region using the first mask as a mask;
implanting a p-type impurity into a second exposed region of the second semiconductor region using a second mask as a mask, the second exposed region being not covered with the second gate insulating film and the second gate electrode, the second mask covering the first semiconductor region, the first gate insulating film, the first gate electrode, and the element-isolation insulating film adjacent to the first semiconductor region; and
performing heat treatment of the first exposed region and the second exposed region to form the first source region, the first drain region, the second source region, and the second drain region.

17. The method according to claim 16, wherein the n-type impurity includes As.

18. The method according to claim 17, wherein a dose amount of the n-type impurity is not less than 3×10¹⁵ atoms/cm².

19. The method according to claim 17, wherein the p-type impurity includes B.

20. The method according to claim 16, wherein a width of the recess along a direction from the first opening toward the second opening increases along a direction from an interior of the semiconductor layer toward the major surface of the semiconductor layer.
